(19) United States
(12) Patent Application Publication
(10) Pub. No.: US 2022/0028758 A1
(43) Pub. Date: Jan. 27, 2022

(54) BACKSIDE POWER DISTRIBUTION NETWORK (PDN) PROCESSING

(71) Applicant: QUALCOMM Incorporated, San Diego, CA (US)

(72) Inventors: Stanley Seungchul SONG, San Diego, CA (US); Jonghae KIM, San Diego, CA (US); Periannan CHIDAMBARAM, San Diego, CA (US)

(21) Appl. No.: 16/937,426

(22) Filed: Jul. 23, 2020

(51) Int. Cl. H01L 23/48; H01L 23/528; H01L 23/532; H01L 21/768

(52) U.S. Cl. CPC H01L 23/481; H01L 21/76898; H01L 23/53228; H01L 23/528

(57) ABSTRACT

Disclosed is a semiconductor die with a through substrate via (TSV) structure having improved electrical characteristics suitable for backside power distribution networks (PDNs), and a method for making same. According to some aspects, a semiconductor die includes a substrate having a front side and a back side and includes a TSV extending from the back side of the substrate towards the front side of the substrate. The TSV includes a first portion extending from the back side of the substrate towards the front side of the substrate and having a first cross sectional area and a second portion extending from the first portion towards the front side of the substrate and having a second cross sectional area smaller than the first cross sectional area. A conductor is disposed within the TSV. According to some aspects, the first portion of the TSV is trench structure.

### FIELD OF DISCLOSURE

This disclosure relates generally to wafer fabrication methods, and more specifically, but not exclusively, to backside power distribution networks (PDNs) and fabrication techniques thereof.

### BACKGROUND

One technique to reduce the size of integrated circuits is to use a backside power distribution network (PDN), in which through substrate vias (TSVs) are used to supply power through the wafer substrate, i.e., from the back side of the substrate to devices on the front side of the substrate.

FIG. 1 shows a portion of an example substrate 100 upon which has been fabricated a complementary metal-oxide semiconductor (MOS) device 102. Buried power rails (BPRs) 104 provide V_{DD} and V_{SS} to the device 102. The BPRs 104 are electrically coupled to a metal structure 106, such as a first layer metal power bus, via vertical conductors 108.

FIGS. 2A through 2C show a conventional process for fabricating a backside PDN to supply the BPRs 104. For simplicity, only the substrate 100 and one BPR 104 is shown. Because the power will be routed through the substrate 100, the wafer is subjected to a backside grinding process to thin the substrate before etching the TSVs. Because this backside grinding process is difficult to control precisely, this limits how thin the substrate wafers are typically ground. As a result, wafers are typically ground only to a point where the substrate is thin enough for nano-TSV formation, e.g., about 3000 nm. The result of the grinding process is shown in FIG. 2A. FIG. 2B shows the result of a TSV etch process: the creation of roughly cylindrical passages 200 through the substrate 100 and into the BPR 104. FIG. 2C shows the finished product having a set of TSVs 202 with liners 204 as created using a dual-damascene process.

However, the thickness of the substrate 100 is large compared to the diameter of a typical TSV 202, which results in a TSV 202 with a high aspect ratio, causing high contact resistance and creating a narrow margin for process defects. For example, a TSV 202 with a typical diameter of 100 nm has a 30:1 aspect ratio.

Accordingly, there is a need for systems, apparatus, and methods that overcome the deficiencies of conventional backside PDN processing, including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In accordance with the various aspects disclosed herein, at least one aspect includes a semiconductor die with a through substrate via (TSV) structure having improved electrical characteristics suitable for backside power distribution networks (PDNs). The semiconductor die includes a substrate having a front side and a back side and includes a TSV extending from the back side of the substrate towards the front side of the substrate. The TSV includes a first portion extending from the back side of the substrate towards the front side of the substrate and having a first cross sectional area. The TSV also includes a second portion extending from the first portion towards the front side of the substrate and having a second cross sectional area smaller than the first cross sectional area. A conductor is disposed within the TSV. According to some aspects, the first portion of the TSV is trench structure.

In accordance with the various aspects disclosed herein, at least one aspect includes, a method for fabricating a semiconductor die with a TSV structure having improved characteristics suitable for PDNs. The method includes providing a substrate having a front side and a back side. The method also includes providing a TSV extending from the back side of the substrate towards the front side of the substrate. The TSV includes a first portion extending from the back side of the substrate towards the front side of the substrate and having a first cross sectional area. The TSV includes and a second portion extending from the first portion towards the front side of the substrate and having a second cross sectional area smaller than the first cross sectional area. A conductor is disposed within the TSV. According to some aspects, the first portion of the TSV is trench structure.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 shows a portion of an example substrate upon which has been fabricated a complementary metal-oxide semiconductor (MOS) device that is powered by buried power rails (BPRs);

FIGS. 2A through 2C show a conventional process for fabricating a backside power distribution network (PDN) to supply the example device shown in FIG. 1;

FIG. 3 is a flowchart illustrating an exemplary partial method for manufacturing a semiconductor die in accordance with some examples of the disclosure;

FIGS. 4A through 4D illustrate an exemplary process for fabricating a semiconductor die in accordance with one or more aspects of the disclosure;

FIG. 5 is a perspective view of a portion of a semiconductor die fabricated according to a process in accordance with some aspects of the disclosure;

FIG. 6 illustrates an exemplary mobile device in accordance with one or more aspects of the disclosure; and

FIG. 7 illustrates various electronic devices that may be integrated with any of the aforementioned integrated device or semiconductor die in accordance with one or more aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

In order to fully illustrate aspects of the design of the present disclosure, methods of fabrication are presented. Other methods of fabrication are possible, and the discussed fabrication methods are presented only to aid understanding of the concepts disclosed herein.

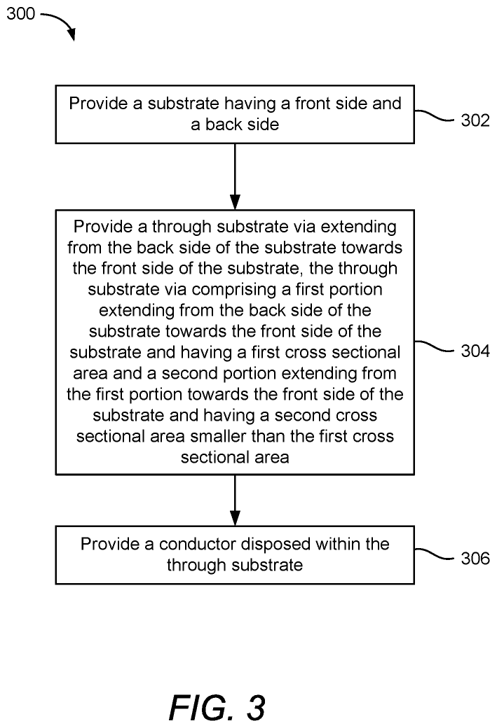

FIG. 3 is a flowchart illustrating an exemplary partial method 300 for manufacturing a semiconductor die in accordance with some examples of the disclosure. As shown in FIG. 3, the partial method 300 may begin in block 302 with providing a substrate having a front side and a back side. The partial method 300 may continue in block 304 with providing a TSV extending from the back side of the substrate towards the front side of the substrate, the TSV comprising a first portion extending from the back side of the substrate towards the front side of the substrate and having a first cross sectional area, and a second portion extending from the first portion towards the front side of the substrate and having a second cross sectional area smaller than the first cross sectional area. The partial method 300 may continue in block 306 with providing a conductor disposed within the TSV.

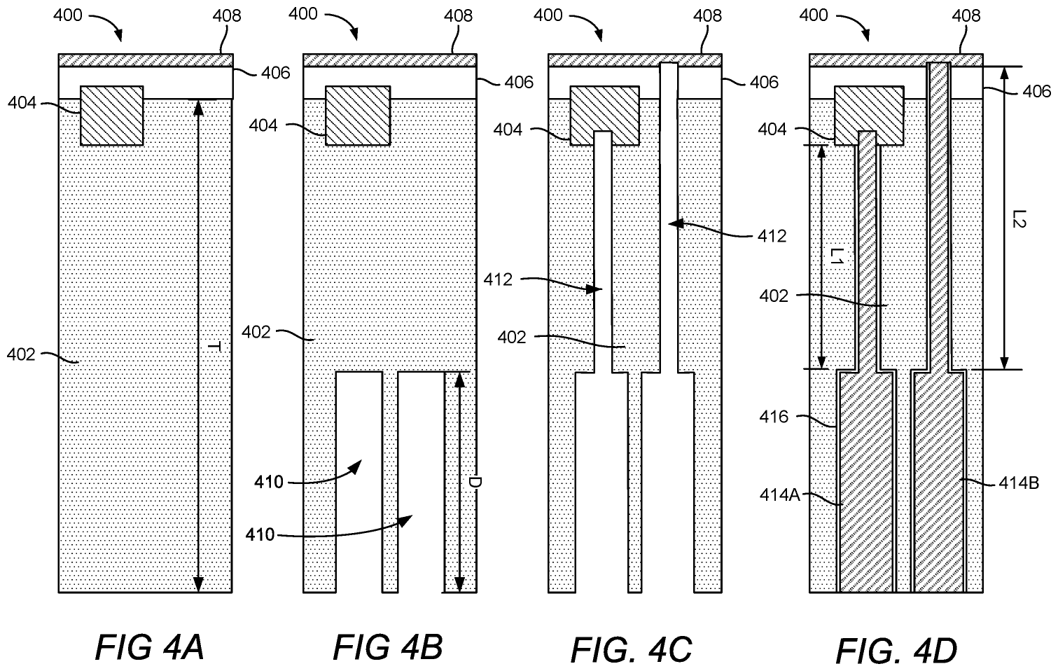

FIGS. 4A through 4D illustrate an exemplary process for fabricating a semiconductor die 400 having TSVs with improved characteristics suitable for use as part of a backside PDN in accordance with one or more aspects of the disclosure. These figures are not to scale.

FIG. 4A illustrates a partial process portion in which a substrate 402 has been ground to some thickness T. Devices and structures have been fabricated on the front side of the substrate 402, but for simplicity, only a few structures are shown in FIGS. 4A through 4D: a buried power rail (BPR) 404, an insulating layer 406, and a metal layer 408. It will be understood that these structures are shown for illustrative purposes only and are not limiting.

FIG. 4B shows a partial process portion in which trenches are etched into the substrate 402 to ultimately form a first portion 410 of a TSV. In FIG. 4B, the trenches have a depth D.

FIG. 4C shows a partial process portion in which through substrate vias (TSVs) are etched into the substrate 402 to form a second portion 412 of a TSV.

FIG. 4D shows a partial process portion in which backside power distribution network (PDN) metallization occupies the trenches and TSVs, creating conductors 414A and 414B, which are used as backside power conduits as part of a backside PDN. This technique may be referred to as a trench first, TSV last (TFTL) method, and the resulting structure may be referred to as a trench-and-TSV structure. As shown in FIG. 4D, the trench-and-TSV structure can be used to provide a power connection to a structure within the substrate 402, such as BPR 404, and also to provide a power connection to a structure built upon the substrate 402, such as metal layer 408, by controlling the depth of the TSV etch process. For damascene processes, copper is used for the conductors 414A and 414B, and isolation layers 416 (also known as liners) isolate the copper from the substrate 402, which is silicon. However, a trench-and-via structure is equally applicable to non-damascene processes, in which case an isolation layer 416 may not be present.

As can be seen in FIG. 4D, the aspect ratio of the conductors 414A and 414B is much improved over the conventional TSVs 202 used for backside connections. For example, for a wafer with a thickness T of 3000 nm and a TSV diameter of 100 nm, a conventional TSV 202 has an aspect ratio of 30:1. In comparison, for a trench having a depth D of 1000 nm, L1 is slightly less than 2000 nm and l2 is slightly more than 2000 nm. As a result, metallization structure 414A has an aspect ratio slightly less than 20:1, and metallization structure 414B has an aspect ratio slightly more than 20:1, both being an improvement over conventional methods. Likewise, if a deeper trench is used, e.g., D=2000 nm, the aspect ratios of conductors 414A and 414B are approximately 10:1. The lower aspect ratios result in lowered resistance in the backside PDN, which leads to lower power consumption and better performance. Furthermore, the use of trenches means that the thickness T of substrate 402 can be greater than 3000 nm, i.e., it is no longer necessary to grind the substrate down to that thickness, with the benefits that the process is less time consuming and less fraught with failures caused by process inaccuracies. The depth D of the trench can be adjusted to accommodate the increased thickness T of the substrate 402.

It will be appreciated that the foregoing fabrication process was provided merely as general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

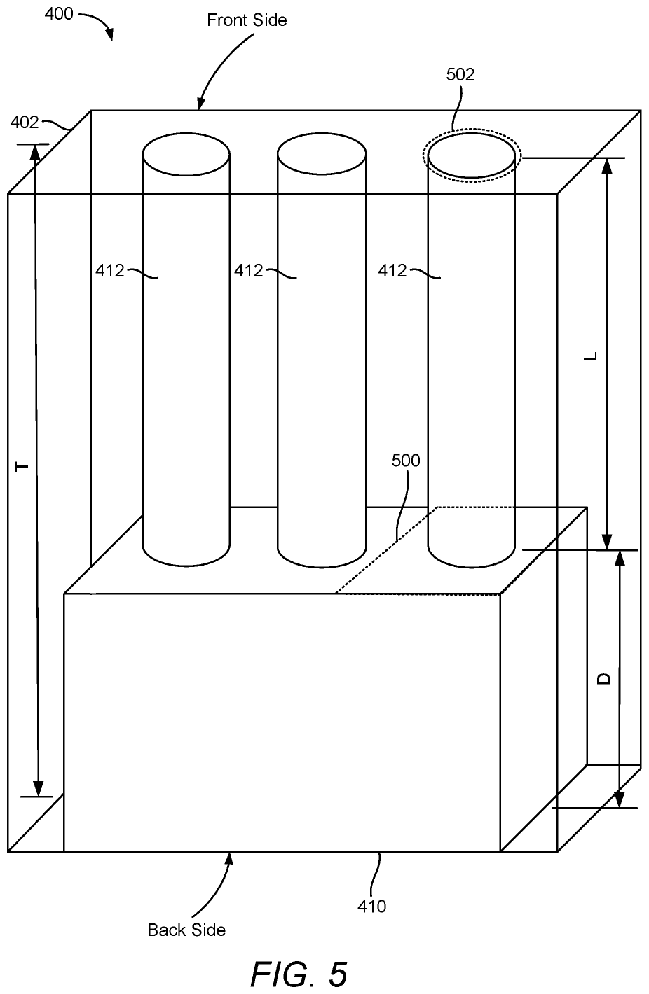

FIG. 5 is a perspective view of a portion of a semiconductor die 400 fabricated according to a process in accordance with some aspects of the disclosure. FIG. 5 shows a portion of a semiconductor die 400 that includes a substrate 402 of thickness T having a front side and a back side, and a TSV extending from the back side of the substrate 402 towards the front side of the substrate 402. The TSV includes a first portion 410 that extends from the back side of the substrate towards the front side of the substrate for a distance D and that has a first cross-sectional area 500, and also includes a second portion 412 that extends from the first portion 410 towards the front side of the substrate 402 for a distance L and that has a second cross-sectional area 502 smaller than the first cross-sectional area 500. The TSV first portion 410 and second portion 412 are filled with a conductor material (not shown in FIG. 5) that forms a conductor 414 from the back side of the substrate 402 towards the front side of the substrate 402.

According to some aspects, the conductor 414 is part of a backside PDN. According to some aspects, the first portion 410 of the TSV is a trench structure. According to some aspects, the conductor 414A is electrically coupled to a metallization layer, such as BPR 404, for example, embedded within the substrate 402. According to some aspects, the second portion 412 of the TSV extends to or beyond the front side of the substrate. According to some aspects, the conductor 414B is electrically coupled to a metal layer 408 located on or above the front side of the substrate 402. According to some aspects, such as in a damascene process, the conductor 414 is separated from the substrate 402 by an isolation layer 416. According to some aspects, the conductor 414 contains copper. According to some aspects the semiconductor die 400 is incorporated into an apparatus such as, but not limited to, a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Semiconductor die 400 provides several technical advantages, including but not limited to the following. Using a trench structure for the first portion 410 of the TSV has at least two benefits: the trench structure has a larger cross-sectional area 500 than the cross-sectional area 502 of the etched nano-TSV, which lowers the resistance of the first portion 410; and the length L of the second portion 412 of the TSV is much less than T, which means that the aspect ratio of the second portion 412 of the TSV is much lower than for conventional TSVs 202, resulting in lower resistance for the entire TSV compared to conventional TSVs 202. Moreover, the first portion 410 may be creating using any technique that results in a larger cross-sectional area 500 compared to the cross-sectional area 502 of conventional etched TSV structures. Furthermore, in the example illustrated in FIG. 5, the entirety of the TSV first portion 410 and second portion 412 may be filled with a conductor such that all three of the second portions 412 are electrically connected together via a common first portion 410, but alternatively each second portion 412 in FIG. 5 may have is own separate first portion 410, such that the second portions 412 are not electrically connected together. Likewise, any combination of the two alternatives above may be used.

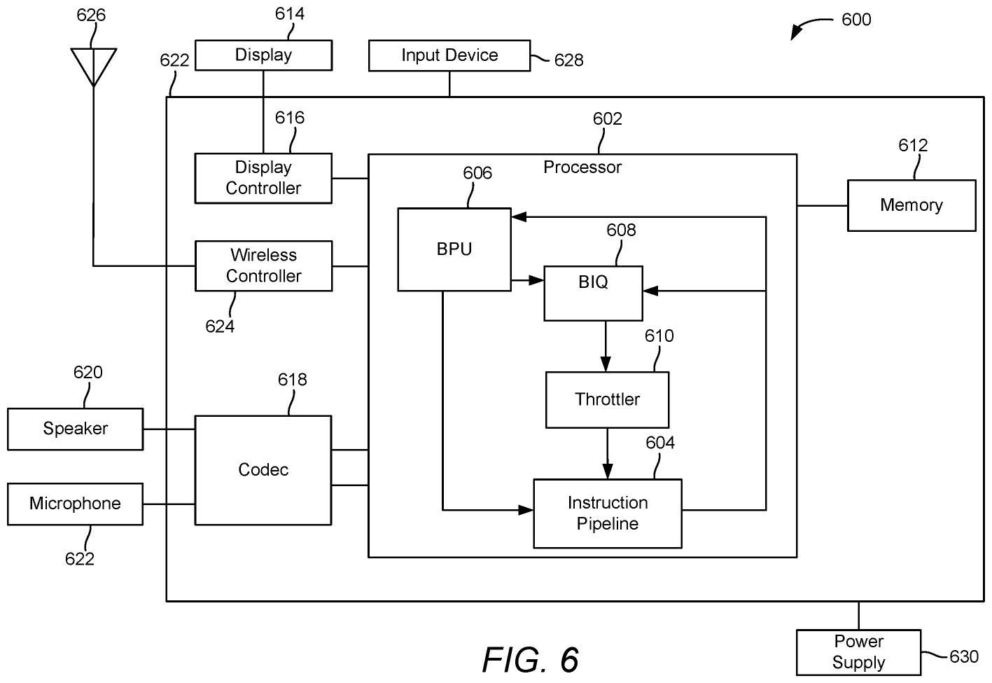

FIG. 6 illustrates an exemplary mobile device in accordance with some examples of the disclosure. Referring now to FIG. 6, a block diagram of a mobile device that is configured according to exemplary aspects is depicted and generally designated mobile device 600. According to some aspects, mobile device 600 may be configured as a wireless communication device. As shown, mobile device 600 includes processor 602. Processor 602 is shown to comprise instruction pipeline 604, buffer processing unit (BPU) 606, branch instruction queue (BIQ) 608, and throttler 610 as is well known in the art. Other well-known details (e.g., counters, entries, confidence fields, weighted sum, comparator, etc.) of these blocks have been omitted from this view of processor 602 for the sake of clarity. Processor 602 may be communicatively coupled to memory 612 over a link, which may be a die-to-die or chip-to-chip link. Mobile device 600 also includes display 614 and display controller 616, with display controller 616 coupled to processor 602 and to display 614.

In some aspects, FIG. 6 may include coder/decoder (CODEC) 618 (e.g., an audio and/or voice CODEC) coupled to processor 602; speaker 620 and microphone 622 coupled to CODEC 618; and wireless controller circuits 624 (which may include a modem, radio frequency (RF) circuitry, filters, etc., which may be implemented using one or more flip-chip devices, as disclosed herein) coupled to wireless antenna 626 and to processor 602.

In a particular aspect, where one or more of the above-mentioned blocks are present, processor 602, display controller 616, memory 612, CODEC 618, and wireless controller circuits 624 can be included in a system-in-package or system-on-chip device, including but not limited to semiconductor die 400, which may be implemented in whole or part using the techniques disclosed herein. Input device 628 (e.g., physical or virtual keyboard), power supply 630 (e.g., battery), display 614, input device 628, speaker 620, microphone 622, wireless antenna 626, and power supply 630 may be external to system-on-chip device and may be coupled to a component of system-on-chip device, such as an interface or a controller.

It should be noted that although FIG. 6 depicts a mobile device, the processor 602 and memory 612 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

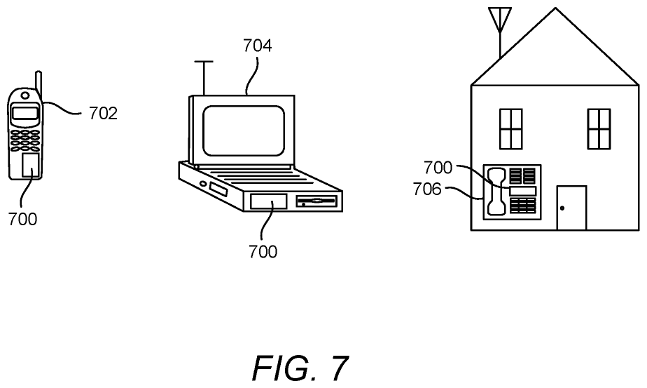

FIG. 7 illustrates various electronic devices that may be integrated with any of the aforementioned integrated device or semiconductor device 700, which may be semiconductor die 400, in accordance with various examples of the disclosure. For example, a mobile phone device 702, a laptop computer device 704, and a fixed location terminal device 706 may each be considered generally user equipment (UE) and may include a package 300 as described herein, for example. The semiconductor die 400 may be, for example, any of the integrated circuits, dies, integrated devices, integrated device packages, integrated circuit devices, device packages, integrated circuit (IC) packages, package-on-package devices described herein. The devices 702, 704, 706 illustrated in FIG. 7 are merely exemplary. Other electronic devices may also feature device including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed packages, devices, and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into a flip-chip or other package. The packages may then be employed in devices described herein.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

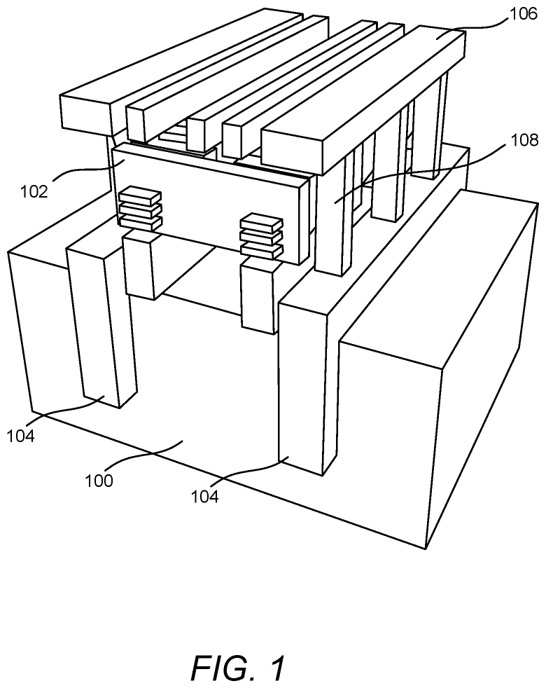

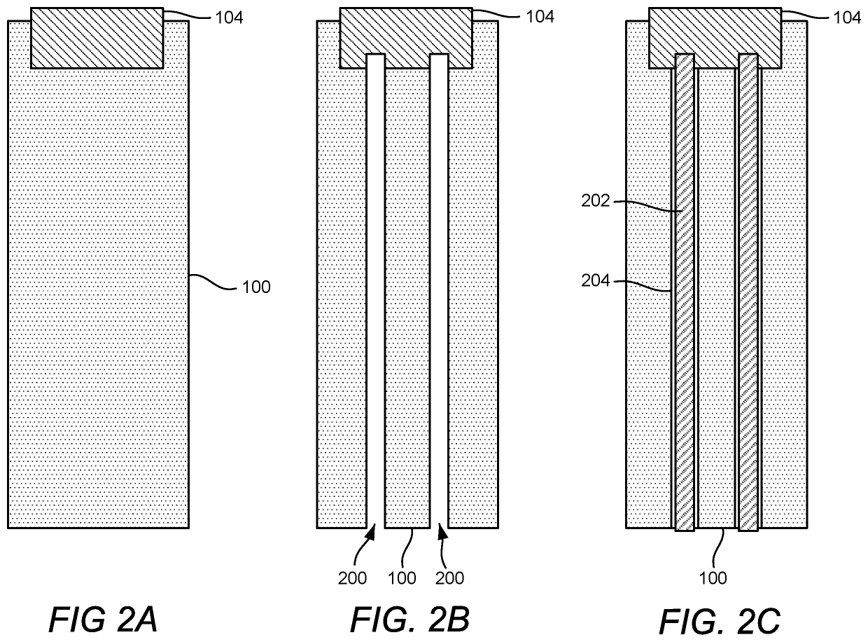

One or more of the components, processes, features, and/or functions illustrated in FIGS. 1-7 may be rearranged and/or combined into a single component, process, feature or function or incorporated in several components, processes, or functions. Additional elements, components, processes, and/or functions may also be added without departing from the disclosure. It should also be noted that FIGS. 1-7 and corresponding description in the present disclosure are not limited to dies and/or ICs. In some implementations, FIGS. 1-7 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), wide-band CDMA (W-CDMA), time division multiple access (TDMA), frequency division multiple access (FDMA), orthogonal frequency division multiplexing (OFDM), global system for mobile communications (GSM), the third generation partnership project (3GPP) long term evolution (LTE), fifth generation (5G) new radio (NR), Bluetooth (BT), Bluetooth low energy (BLE), IEEE 802.11 (WiFi), and IEEE 802.15.4 (Zigbee/Thread) or other protocols that may be used in a wireless communications network or a data communications network. Bluetooth low energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Further, those of skill in the art will appreciate that the various illustrative logical blocks, modules, circuits, and algorithm actions described in connection with the examples disclosed herein may be implemented as electronic hardware, computer software, or combinations of both. To clearly illustrate this interchangeability of hardware and software, various illustrative components, blocks, modules, circuits, and actions have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Although some aspects have been described in connection with a device, it will be understood that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer or an electronic circuit. In some examples, some or a plurality of the method actions can be performed by such an apparatus.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or a plurality of claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor die comprising:
a substrate having a front side and a back side;
a through substrate via (TSV) extending from the back side of the substrate towards the front side of the substrate, the TSV comprising:
a first portion extending from the back side of the substrate towards the front side of the substrate and having a first cross sectional area; and
a second portion extending from the first portion towards the front side of the substrate and having a second cross sectional area smaller than the first cross sectional area; and
a conductor disposed within the TSV.

2. The semiconductor die of claim 1, wherein the conductor comprises a backside power distribution network (PDN).

3. The semiconductor die of claim 1, wherein the first portion of the TSV comprises a trench structure.

4. The semiconductor die of claim 1, wherein the conductor is electrically coupled to a metallization layer disposed within the substrate.

5. The semiconductor die of claim 1, wherein the second portion of the TSV extends to or beyond the front side of the substrate.

6. The semiconductor die of claim 5, wherein the conductor extends beyond the front side of the substrate and is electrically coupled to a metallization layer disposed on or above the front side of the substrate.

7. The semiconductor die of claim 1, wherein the conductor is separated from the substrate by an isolation layer.

8. The semiconductor die of claim 1, wherein the conductor comprises copper.

9. The semiconductor die of claim 1, in which the semiconductor die is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

10. A method of fabricating a semiconductor die, the method comprising:
providing a substrate having a front side and a back side;
providing a through substrate via (TSV) extending from the back side of the substrate towards the front side of the substrate, the TSV comprising a first portion extending from the back side of the substrate towards the front side of the substrate and having a first cross sectional area, and a second portion extending from the first portion towards the front side of the substrate and having a second cross sectional area smaller than the first cross sectional area; and
providing a conductor disposed within the TSV.

11. The method of claim 10, wherein the conductor comprises a backside power distribution network (PDN).

12. The method of claim 10, wherein the first portion of the TSV comprises a trench structure.

13. The method of claim 10, wherein the conductor is electrically coupled to a metallization layer disposed within the substrate.

14. The method of claim 10, wherein the second portion of the TSV extends to or beyond the front side of the substrate.

15. The method of claim 14, wherein the conductor extends beyond the front side of the substrate and is electrically coupled to a metallization layer disposed on or above the front side of the substrate.

16. The method of claim 10, wherein the conductor is separated from the substrate by an isolation layer.

17. The method of claim 10, wherein the conductor comprises copper.

18. The method of claim 10, further comprising incorporating the semiconductor die into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
